(19) United States
(12) Patent Application Publication
(10) Pub. No.: US 2026/0040513 A1
(43) Pub. Date: Feb. 5, 2026

(54) ELECTROMAGNETIC INTERFERENCE-SHIELDED BATTERY PACK FOR ELECTRIC VEHICLES

(71) Applicant: BOMBARDIER RECREATIONAL PRODUCTS INC., Valcourt (CA)

(72) Inventors: Mathieu DUQUETTE, Sherbrooke (CA); Alain LAVOIE, Drummondville (CA); Denis BOURASSA, Valcourt (CA); Cong-Long NGUYEN, Sherbrooke (CA); Adrien LETELLIER, Sherbrooke (CA); Edward ROUSSEAU, Bonsecours (CA)

(21) Appl. No.: 19/283,851

(22) Filed: Jul. 29, 2025

Related U.S. Application Data
(60) Provisional application No. 63/677,710, filed on Jul. 31, 2024.

(51) Int. Cl. H05K 9/00; H01M 10/42; H01M 50/249; H01M 50/284

(52) U.S. Cl. CPC H05K 9/0049; H01M 10/425; H01M 50/249; H01M 50/284; H05K 9/0083; H05K 9/0084; H05K 9/009; H01M 2010/4271

(57) ABSTRACT

A battery pack with electromagnetic compatibility (EMC) for an electric vehicle is presented that includes a battery pack housing, at least one battery module enclosed within the battery pack housing, and an electronics assembly enclosed within the battery pack housing, in which the electronics assembly comprises a DC-DC converter and an electronics assembly casing, wherein at least one of the electronics assembly and battery pack housing includes an electromagnetic interference (EMI) shield to enable EMC. The electronics assembly includes a battery management system (BMS) circuit board and a DC-DC converter control circuit board and a DC-DC converter power electronics board. The electronics assembly is of substantially a same dimension of a battery module, in which the EMI shield comprises at least one of a metallic screen, metallic wires, a metallic tape, a metallic sheet, a metallic coating, paramagnetic materials, carbon based materials and metallic and/or carbon particle-infused composites.

### CROSS-REFERENCE TO RELATED APPLICATIONS

The present application claims priority to U.S. Provisional Patent Application No. 63/677,710, entitled “Electromagnetic Interference-Shielded Battery Pack for Electric Vehicles,” filed Jul. 31, 2024, the entirety of which is incorporated by reference herein.

### FIELD OF TECHNOLOGY

The present technology relates to battery pack configurations for electric vehicles.

### BACKGROUND

The trend towards the electrification of road vehicles has also impacted powersport vehicles, such as: motorcycles, snowmobiles, all-terrain vehicles, personal watercrafts, etc. Accordingly, there are many efforts underway to increase the range, performance, and maximization of electric power supplied to such electric vehicles while also managing the efficient and satisfactory electric power supply to systems that provide various operational and monitoring features, such as, navigation, communications, range estimation, component fault/failure reporting, etc. However, the smaller footprint of powersports vehicles relative to other vehicles requires a more compact electrical system, in order to achieve better performances and higher energy density.

Electromagnetic interference (EMI) exists generally in one of two forms, either conducted or radiated. When describing problematic EMI between a source and a victim component, the EMI will typically exist as both types at different locations between the source and the victim. Conducted EMI travels through electrical conductors and radiated EMI is generally emitted from a conductor, which acts as an antenna. Radiated EMI travels through space from the source and upon reaching the victim, couples to a conductor in the victim, inducing conducted EMI. The usage of the term EMI in the scope of the present technology is generally meant in the context of radiated EMI.

Electric vehicles encompass a multitude of electrical/electronic components and their related processing logic circuitry which, by their very nature, are susceptible to the disruptive influence of electromagnetic interference. Other components, such as power inverters or DC power converters, will emit highly disruptive levels of EMI during use, which can affect susceptible components onboard the vehicle, as well as any other susceptible devices which may be located within proximity. It is therefore important for such vehicles to both be compatible with any electromagnetic environment in which they may operate in and, at the same time, not emit levels of electromagnetic energy which may cause EMI in any other devices in the vicinity, otherwise known as electromagnetic compatibility (EMC). That is, in a vehicle not meeting the required EMC target, whether the target is established by a certain standard, or is set to enable proper vehicle function in its electromagnetic environment, EMI may induce a variety of electrical disturbances. These disturbances may manifest themselves as, for example, transient current/voltage spikes in electronic signals, conductors, and/or localized circuit grounds etc., that may disrupt the proper operation of processors and logic circuits, as well as result in the damage of voltage-sensitive components. Moreover, the trend of the electrical architecture for these vehicles is to make electrical resources more compact to maintain a relatively small footprint. However, because radiated EMI intensity is closely related to distances from the EMI source, such compactness leads to components radiating disruptive levels of EMI being in relatively close enough proximity to susceptible components, thereby increasing the chances that EMC targets will not to be achieved without adequate mitigation measures, such as EMI shielding.

Therefore, there exists some interest in facilitating the achievement of EMC targets, by the mitigation of both emission and susceptibility to EMI effects and influences in battery pack arrangements for electric vehicles.

### SUMMARY

It is an overall object of the present technology to mitigate at least some of the issues associated with EMI influences in battery pack arrangements for electric vehicles that remain present in the prior art.

In accordance with an embodiment of the present technology, there is provided a battery pack with electromagnetic compatibility (EMC) for an electric vehicle, comprising a battery pack housing; at least one battery module enclosed within the battery pack housing; and an electronics assembly enclosed within the battery pack housing, in which the electronics assembly comprises a DC-DC converter and an electronics assembly casing, wherein at least one of the electronics assembly and battery pack housing includes an EMI shield to enable EMC.

In some aspects, the electronics assembly is of substantially a same dimension of a battery module and the EMI shield comprises at least one of a metallic screen, metallic wires, a metallic tape, a metallic sheet, a metallic coating, paramagnetic materials, carbon based materials and metallic and/or carbon particle-infused composites.

In some aspects, the electronics assembly includes a battery management system (BMS) circuit board and a DC-DC converter control circuit board and a DC-DC converter power electronics board.

In some aspects, at least one of the outer or inner surfaces of the battery pack housing includes at least one of a metallic screen, metallic wires, a metallic tape, a metallic sheet, and a metallic coating to provide an EMI shield.

In accordance with another embodiment of the present technology, there is provided an electronics assembly for a battery pack with electromagnetic compatibility (EMC) for an electric vehicle comprising a DC-DC converter and an electronics assembly casing configured to house the DC-DC converter, wherein at least one of the electronics assembly casing and the DC-DC converter incorporates an EMI shield to enable EMC.

In some aspects, the electronics assembly includes a battery management system (BMS) circuit board and the DC-DC converter comprises a DC-DC converter control circuit board and a DC-DC converter power electronics board.

In some aspects, the EMI shield comprises at least one of a metallic screen, metallic wires, a metallic tape, a metallic shield, a metallic coating, carbon based materials, paramagnetic materials, and a metallic and/or carbon particle-infused composite.

Within the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Furthermore, the phrase “at least one of A and B” is intended to mean A only, B only or both A and B.

Additional and/or alternative features, aspects and advantages of embodiments of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a top side perspective external view of a battery pack for an electric vehicle, in accordance with a non-limiting embodiment of the present technology;

FIG. 2 illustrates a partially exploded view of the general components enclosed by a housing of the battery pack of FIG. 1, in accordance with a non-limiting embodiment of the present technology;

FIG. 3 illustrates an exploded view of an electronics assembly of the battery pack, in accordance with a non-limiting embodiment of the present technology;

FIG. 4 illustrates a different exploded view the electronics assembly enclosed by the battery pack, in accordance with a non-limiting embodiment of the present technology; and

FIG. 5 illustrates the top side perspective external view of the top and bottom covers of the battery pack housing containing EMI shielding materials, in accordance with a non-limiting embodiment of the present technology.

It should be noted that, unless otherwise explicitly specified herein, the drawings are not necessarily to scale.

### DETAILED DESCRIPTION

The present technology will be described herein with respect to a battery pack 100 for powering an electric vehicle and, in particular, powersport vehicles. The battery pack 100 may be incorporated in a variety of electric vehicle types including, but not limited to, electric motorcycles, electric snowmobiles, electric all-terrain vehicles (ATVs), two-wheeled straddle-seat electric vehicles, three-wheeled electric vehicles, electric side-by-side vehicles, four-wheeled electric vehicles, electric watercraft, etc. It is contemplated that at least some aspects of the present technology may also be used in electric vehicles other than electric powersport vehicles.

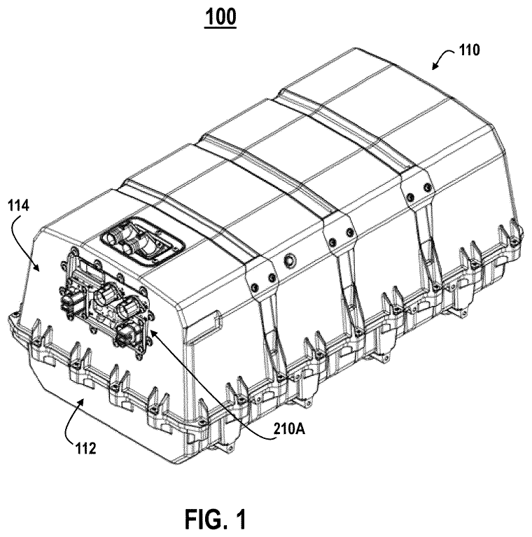

FIG. 1 depicts a top side perspective external view of a battery pack 100 for an electric vehicle, in accordance with the non-limiting embodiments of the present technology. As shown, the battery pack 100 comprises a battery housing 110 for enclosing the various components contained by the battery pack 100. The battery housing 110 includes a first cover 114 and a second cover 112, in which the first cover 114 is selectively fastened to the second cover 112. In the present embodiment, the first cover 114 is a top cover and the second cover 112 is a bottom cover. It is contemplated that the first and second covers 112, 114 could be secured together in a variety of different ways that allow for the selective attachment/detachment of the covers 112, 114, such as, for example, tabs, latches, spring fasteners, etc.

In the illustrated embodiment, the battery housing 110 has a generally rectangular cuboid form. It is contemplated that the battery housing 110 could be differently shaped depending on the available space and configuration of the electric vehicle. As will be described in greater detail below regarding EMI shielding, the material used for the top and bottom covers 112, 114 of the housing 110 may comprise carbon-based materials, metal(s), metallic and/or carbon particle-infused composite(s), paramagnetic material(s) and may further incorporate a metallic screen, metallic wires, metallic tape, metallic sheets, metallic coating, etc.

FIG. 1 also indicates that battery housing 110 contains a connection interface panel 210A for connecting to other vehicle components (not shown). As will be described in greater detail below, the connection interface panel 210A is mounted proximate to an electronics assembly 210. The connection interface panel 210A is configured with various connection ports to connect to a variety of components of the electric vehicle including, but not limited to, charger, power inverter, a 12V battery, communications module, etc.

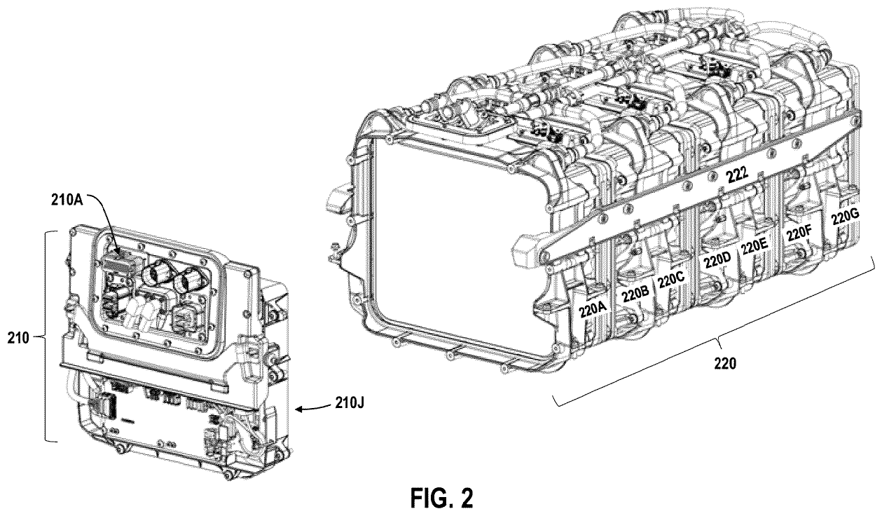

FIG. 2 depicts a partially exploded view of the components enclosed by the battery pack housing 110, in accordance with a non-limiting embodiment of the present technology. Generally, the enclosed components contain an electronics assembly 210 and individual battery modules 220A-220G positioned in proximity to each other and connected in series by busbars 222, thus forming the battery circuit. Each of the enclosed battery modules 220A-220G comprises a plurality of constituent battery cells (not shown).

It will be appreciated that the selection of the number of individual battery modules and/or the selection of constituent battery cells depends, in part, on the particular electric vehicle and intended use/operations of the vehicle which relates to the nominal energy capacity, usable energy capacity, discharge rate, cell chemistry, cell geometry, cell type, etc. of the battery cells. As such, the battery cells may embody different shapes/sizes, such as, cylindrical, rectangular, etc. as well as comprise different cell types, such as, nickel cadmium, lithium ion, etc.

Moreover, the electronics assembly 210 is configured with a substantially similar size and dimension as an individual battery modules 220A-220G. As such, the electronics assembly 210 occupies a compact footprint equivalent to the individual battery modules 220A-220G within the battery pack housing 110.

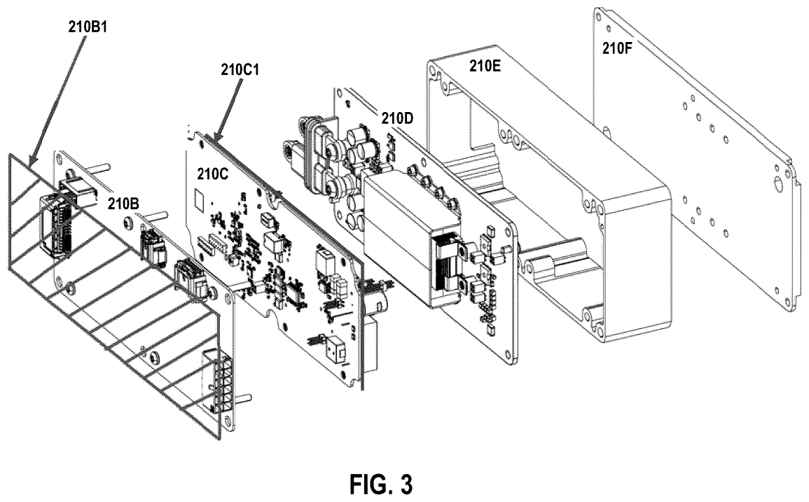

For the internal configuration of electronics assembly 210, FIG. 3 better illustrates the constituent parts of electronics assembly 210, in accordance with a non-limiting embodiment of the present technology. The electronics assembly 210 comprises a battery management system (BMS) circuit board layer 210B, a DC-DC converter control circuit board layer 210C, a DC-DC power electronics circuit board layer 210D, an electronics assembly casing 210E, and a thermal interface plate 210F.

The BMS circuit board layer 210B comprises electronic components (not identified in FIG. 3) configured to control various battery related functions, such as, balance the voltage of the battery cells 146, control recharging of the battery cells 146, control the operating temperature of the battery cells 146, and control shutting off (i.e., disconnect) connectivity to the battery cells, via a battery disconnection unit (BDU), whenever the vehicle is turned off, or in case of detected faulty battery conditions. In addition, the components of the BMS 210B also operates to collect battery status information, such as, for example, state-of-charge (SOC), state-of-health (SOH), state-of-function (SOF), battery temperature, etc.

The DC-DC converter control circuit board layer 210C comprises electronic components (not identified in FIG. 3) configured to control the operations of the DC-DC power electronics circuit board layer 210D. In turn, under the control of the DC-DC converter control circuit board layer 210C, the DC-DC power electronics circuit board layer 210D comprises electronic components (not identified in FIG. 3) configured to convert electrical energy at a high DC voltage, such as supplied by the battery circuit, into electrical energy at a lower DC voltage level for consumption by on-board monitoring/processing/management equipment of the vehicle, which operate at a lower voltage.

It will be appreciated that the electronic components of the DC-DC power electronics circuit board layer 210D implement power transistors to handle the high DC voltage levels, which are operated to perform high frequency switching to achieve the required stable lower DC voltage levels. Additionally, there may be at least one large capacity inductor or coil that is employed by the DC-DC power electronics circuit, in conjunction with the power transistors, to convert the DC voltage level. In so doing, the electronic components of the DC-DC power electronics circuit board layer 210D are a source of internal EMI that may affect the proper functioning of the electronic processing components contained within the battery pack housing 110 or anywhere else inside or outside the vehicle, where susceptible components are located in sufficient proximity.

For at least this reason, as indicated by FIG. 3, the DC-DC converter control circuit board layer 210C further comprises a grounding plane that operates as an EMI shielding layer 210C1 to mitigate the effects of the internally-generated EMI on the electronic processing components of the DC-DC converter control circuit board layer 210C. Relatedly, the BMS circuit board layer 210B may further comprise an EMI shielding 210B1 to mitigate the effects of the EMI internally generated by the DC-DC power electronics circuit on the electronic processing components of the BMS circuit board layer 210B or notably from the power inverter (not shown).

As shown in FIG. 3, the electronics assembly 210 also includes an electronics assembly casing 210E formed from a metallic, carbon based, paramagnetic, or metallic and/or carbon particle-infused composite material, such as a carbon-fiber reinforced polymer, to provide additional protection against internal EMI. Moreover, in operation, electronics assembly casing 210E is configured to receive and encase the BMS circuit board 210B, the DC-DC converter control circuit board 210C, and the DC-DC power electronics circuit board 210D in a layered manner. For example, in a non-limiting embodiment, the layered configuration may comprise the BMS circuit board 210B, followed by the DC-DC converter control circuit board 210C, which is then followed by the DC-DC power electronics circuit board 210D.

The layering of the circuit boards 210B, 210C, and 210D is intentionally designed to provide a compact electronics assembly 210 that will be easily accommodated by the battery housing 110 along side of the racked battery modules 220A-220G while, at the same time, increasing EMC via the EMI shields 210B1, 210C1.

Moreover, the layering of the circuit boards 210B, 210C, 210D within the electronics assembly casing 210E is also intentionally designed to minimize the length of cables/conductors that electrically connect components of the circuit boards 210B, 210C, 210D. By reducing the connecting cables/conductor lengths, the possibility for such connecting cables/conductor to behave like an “antenna” by picking up and/or emitting radiated EMI is reduced, thereby increasing EMC.

Relatedly, the layering of the circuit boards 210B, 210C, 210D further allows for the segregation of high voltage and low voltage conductors. Specifically, the high voltage conductors are disposed along one side of the electronics assembly casing 210E and the low voltage conductors are disposed along the opposite side of the casing 210E. This segregation further reduces the possibility of inductive and/or capacitive coupling, which can otherwise be classified as radiated EMI, between the high voltage and low voltage conductors.

Finally, the electronics assembly 210 further includes a thermal interface plate 210F configured to move thermal energy generated by the DC-DC power electronics circuit board 210D components away from the electronics assembly 210, to the thermal management system of the battery pack 100. As such, the thermal interface plate 210F comprises a thermally-conductive metal which provides an additional plane of protection against internally-generated EMI.

With this said, the disclosed embodiments presented thus far have been directed to providing detailed configurations of constituent components of the electronics assembly 210, which have been designed to mitigate the effects of internally-generated EMI within the electronics assembly 210 and battery housing 110 of an electric vehicle. However, there also exists the possibility of EMI generated outside of the electronics assembly 210/battery housing 110 that may disrupt the proper operations of the electronic processing components contained within the electronics assembly 210 and battery housing 110. For example, such externally-generated EMI may be produced by power inverters that are configured to adjust the DC-AC conversion frequency to change motor speeds. As another example, power chargers that communicatively-interface with the connection interface panel 210A to recharge the battery modules 220A-220G operate at different charging current levels and charging speeds that may also produce externally-generated EMI.

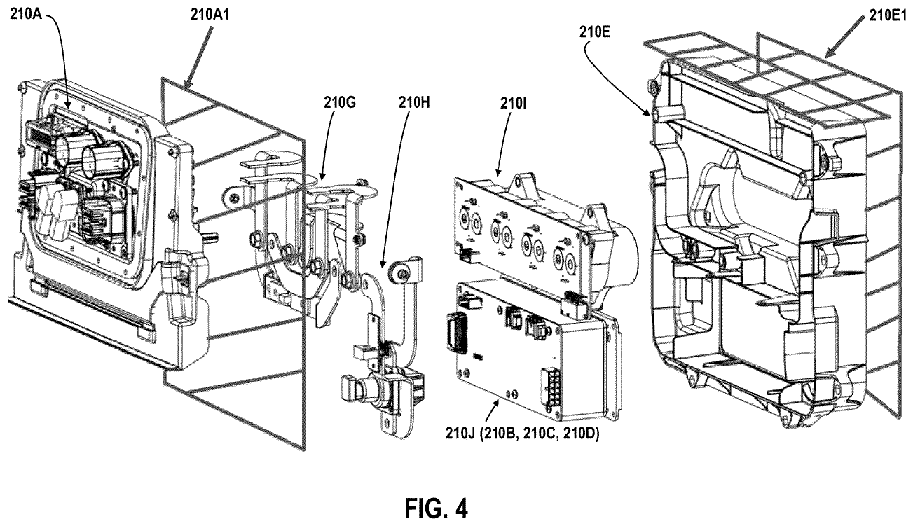

To this end, the embodiments disclosed thus far provide configurations and arrangements with reference to mitigating internally-generated EMI. However, it will be appreciated that such configurations/arrangement equally apply to mitigating externally-generated EMI in order to increase overall EMC. With this said, FIG. 4 illustrates a different exploded view of the electronics assembly 210, in accordance with a non-limiting embodiment of the present technology that further mitigates externally-generated EMI to increase EMC. In this view, FIG. 4 shows the previously disclosed connection interface panel 210A and the electronics assembly casing 210E in addition to depicting a busbar circuit 210G, a current-sensor and pyrofuse circuit 210H, a contactor assembly 210I, and an electronics subassembly 210J comprising the previously disclosed BMS circuit board 210B, DC-DC converter control circuit board 210C, and DC-DC power electronics circuit board 210D.

The busbar circuit 210G is configured to couple the various signals to/from the connection interface panel 210A to/from the contactor assembly 210I. The current-sensor and pyrofuse circuit 210H is configured with a Hall effect sensor with it's related digital processing circuitry to sense and measure current flows, while the pyrofuse comprises a device configured to sever the busbar connection to terminate all current flow and connectivity to the battery cells, as well as it's related digital processing circuitry, which is configured to receive a corresponding BMS control signal. The current-sensor and pyrofuse circuit 210H both include integrated circuits that are susceptible to EMI. Additionally, the electronics subassembly 210J depicts the assembled combination of the BMS circuit board 210B, the DC-DC converter control circuit board 210C, and the DC-DC power electronics circuit board 210D.

As shown, the connection interface panel 210A may be configured to incorporate an EMI shield 210A1 along its backplane to mitigate any effects of externally-generated EMI from disruptively influencing any of the electronic processing components of electronics assembly 210 that may arise from the power inverters and power chargers.

Moreover, as also shown, the electronics assembly casing 210E may also be configured to incorporate an EMI shield 210E1 that covers the top, bottom, and side surfaces of the electronics assembly casing 210E or any combination thereof these surfaces, to increase EMC.

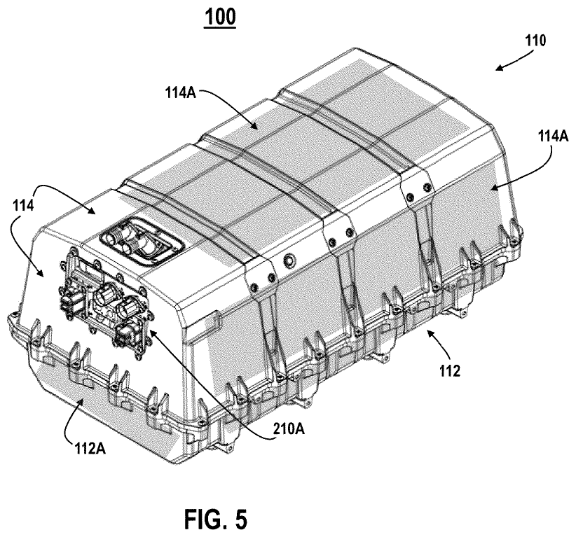

Along similar lines, FIG. 5 illustrates a perspective external view of the first and second covers 112, 114 of the battery pack housing 110 that incorporate EMI shielding materials to increase EMC, in accordance with the non-limiting embodiments of the present technology. That is, the first and second covers 112, 114 of the battery pack housing 110 may further be composed of EMI shielding materials, as indicated by 112A, 114A, respectively. In particular, the first and second cover shielding 112A, 114A may be comprised of materials, such as, metals, carbon based materials, metallic and/or carbon particle-infused composites, paramagnetic materials, etc. that provide EMI shielding mitigating the effects of both externally and internally-generated EMI. Moreover, alternatively or in addition to, the inner surfaces of the first and second covers 112, 114 may further incorporate metallic screens, metallic wires, metallic tape, metallic strips, metallic coatings, etc. configured to provide additional EMI shielding for increased EMC.

In this manner, the disclosed embodiments provide a detailed compact battery pack configuration for an electric vehicle that incorporates EMI shielding features to mitigate the disruptive influence and effects of both, internally-generated and externally-generated EMI on electronic components and increase EMC.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A battery pack with electromagnetic compatibility (EMC) for an electric vehicle, comprising:
a battery pack housing;
at least one battery module enclosed within the battery pack housing; and
an electronics assembly enclosed within the battery pack housing,
the electronics assembly comprising a DC-DC converter and an electronics assembly casing,
wherein at least one of the electronics assembly and battery pack housing includes an electromagnetic interference (EMI) shield to enable EMC.

2. The battery pack of claim 1, wherein the electronics assembly includes a battery management system (BMS) circuit board.

3. The battery pack of claim 2, wherein the electronics assembly is of substantially a same dimension of a battery module.

4. The battery pack of claim 1, wherein the EMI shield comprises at least one of a metallic screen, metallic wires, a metallic tape, a metallic sheet, a metallic coating, paramagnetic materials, carbon based materials and metallic and/or carbon particle-infused composites.

5. The battery pack of claim 4, wherein the EMI shield is configured to increase the EMC of the DC-DC converter.

6. The battery pack of claim 1, wherein the electronics assembly casing comprises at least one of a metallic, carbon based, and a metallic and/or carbon particle-infused composite material.

7. The battery pack of claim 1, further including an EMI shield to at least one surface of the electronics assembly.

8. The battery pack of claim 1, further including an EMI shield to at least one surface of the electronics assembly casing.

9. The battery pack of claim 1, wherein the battery pack housing comprises carbon, metal and/or a metallic and/or carbon particle-infused material that constitutes an EMI shield.

10. The battery pack of claim 1, wherein at least one of the outer or inner surfaces of the battery pack housing includes at least one of a metallic screen, metallic wires, a metallic tape, a metallic sheet, and a metallic coating to provide an EMI shield.

11. The battery pack of claim 1, wherein the DC-DC converter is disposed within the electronics assembly casing.

12. The battery pack of claim 11, wherein the DC-DC converter further comprises a DC-DC converter control circuit board and a DC-DC converter power electronics board.

13. An electronics assembly for a battery pack with electromagnetic compatibility (EMC) for an electric vehicle comprising:
a DC-DC converter; and
an electronics assembly casing configured to house the DC-DC converter,
wherein at least one of the electronics assembly casing and the DC-DC converter incorporates an EMI shield to enable EMC.

14. The electronics assembly of claim 13, wherein the EMI shield comprises at least one of a metallic screen, metallic wires, a metallic tape, a metallic shield, a metallic coating, carbon based materials, paramagnetic materials, and a metallic and/or carbon particle-infused composite.

15. The electronics assembly of claim 13, further including a battery management system (BMS) circuit board.

16. The electronics assembly of claim 13, wherein the electronics assembly casing comprises at least one of a metallic, carbon based and a metallic and/or carbon particle-infused composite material to increase EMC.

17. The electronics assembly of claim 13, wherein the DC-DC converter comprises a DC-DC converter control circuit board and a DC-DC converter power electronics board.
